(19) United States
(12) Patent Application Publication
(10) Pub. No.: US 2025/0158323 A1
(43) Pub. Date: May 15, 2025

(54) CIRCUIT BOARD AND ELECTRONIC APPARATUS

(71) Applicant: Lenovo (Singapore) Pte. Ltd., Singapore (SG)

(72) Inventors: Fumitake Mizoguchi, Kanagawa (JP); Yoshiyuki Shibayama, Kanagawa (JP); Yuichi Onda, Kanagawa (JP); Sara Akiyama, Kanagawa (JP)

(73) Assignee: Lenovo (Singapore) Pte. Ltd., Singapore (SG)

(21) Appl. No.: 18/922,316

(22) Filed: Oct. 21, 2024

(30) Foreign Application Priority Data
Nov. 13, 2023 (JP) 2023-192786

(51) Int. Cl. H01R 13/621; H05K 1/02

(52) U.S. Cl. CPC H01R 13/6215; H05K 1/0215; H05K 2201/093; H05K 2201/1031

(57) ABSTRACT

A circuit board is a circuit board on which a connector for connecting one end of an electronic module is mounted, and includes: a ground pad provided on a surface and configured to fix a first or second support that supports the other end of the electronic module, in which the ground pad includes a first region formed of a metal pattern, a second region formed of a metal pattern with a smaller area than the first region, and a void region that separates the first region and the second region from each other by being provided with no metal pattern, and the ground pad is configured to selectively fix the first support that fits within the first region, and the second support that extends beyond the void region and spans the first region and the second region.

### CROSS-REFERENCE TO RELATED APPLICATIONS

This application claims priority to Japanese Patent Application No. 2023-192786 filed on Nov. 13, 2023, the contents of which are hereby incorporated herein by reference in their entirety.

### BACKGROUND OF THE INVENTION

### Field of the Invention

The present invention relates to a circuit board and an electronic apparatus equipped with the circuit board.

### Description of the Related Art

An electronic apparatus such as a laptop PC is used by connecting an electronic module such as an SSD to a connector of a circuit board (motherboard) on which a CPU is mounted (refer to, for example, Japanese Unexamined Patent Application Publication No. 2020-057737).

### SUMMARY OF THE INVENTION

Typically, one end of the electronic module is connected to the connector mounted on the circuit board, and the other end is fixed to the circuit board with a screw, as described in Japanese Unexamined Patent Application Publication No. 2020-057737. The screw is tightened to a stud member formed with a threaded hole. The stud member is soldered and fixed to a ground pad formed on a surface of the circuit board.

The electronic module as described above may be attached by an operator in a factory or the like, may be replaced by a user himself/herself, or the like. There is a possibility that the screw may fall into a chassis and require time and effort for retrieval, or may result in loss at this time.

Therefore, it is also conceivable to use a support other than the screw as a support that supports the electronic module. Examples of the support other than the screw include a locking component including a cam-shaped member that rotates relative to the stud member. The locking component is used by switching between, for example, a locked position where the other end of the electronic module is pressed, and an unlocked position where the other end is not pressed. However, such a locking component needs to have a rotation direction (installation posture) controlled to a fixed direction when fixed to the ground pad. This is because, in a case where the installation posture is not determined, the locked position and the unlocked position may be mixed when the electronic module is supported in the factory or the like, and work efficiency may decrease.

Meanwhile, the typical fixing method using the screw may also be sufficiently effective depending on the specifications, applications, or the like of the electronic apparatus. However, the versatility of the circuit board decreases in a case where the ground pad provided on the circuit board is a dedicated component that is compatible with only one support, and the product costs of the circuit board and the electronic apparatus equipped with the circuit board increase.

One or more embodiments provide a circuit board and an electronic apparatus including the circuit board that can enhance versatility and reduce costs.

A circuit board according to a first aspect of the present invention is a circuit board on which a connector for connecting one end of an electronic module is mounted, and includes: a ground pad provided on a surface and configured to fix a first or second support configured to support the other end of the electronic module, in which the ground pad includes a first region formed of a metal pattern, a second region formed of a metal pattern with a smaller area than the first region, and a void region configured to separate the first region and the second region from each other by being provided with no metal pattern, and the ground pad is configured to selectively fix the first support that fits within the first region, and the second support that extends beyond the void region and spans the first region and the second region, and allows, in a case where the first support is fixed to the first region, a rotation direction of the first support to be positioned in a fixed direction.

An electronic apparatus according to a second aspect of the present invention includes: a circuit board to which an electronic module is connected, in which the circuit board includes a connector mounted on a surface and to which one end of the electronic module is connected, a ground pad provided on the surface, and a support fixed to the ground pad and configured to support the other end of the electronic module, the ground pad includes a first region formed of a metal pattern, a second region formed of a metal pattern with a smaller area than the first region, and a void region configured to separate the first region and the second region from each other by being provided with no metal pattern, and the support has a shape that fits within the first region, and is fixed to the first region with a rotation direction of the support positioned in a fixed direction.

An electronic apparatus according to a third aspect of the present invention includes: a circuit board to which an electronic module is connected, in which the circuit board includes a connector mounted on a surface and to which one end of the electronic module is connected, a ground pad provided on the surface, and a support fixed to the ground pad and configured to support the other end of the electronic module, the ground pad includes a first region formed of a metal pattern, a second region formed of a metal pattern with a smaller area than the first region, and a void region configured to separate the first region and the second region from each other by being provided with no metal pattern, and the support has a shape that extends beyond the void region and spans the first region and the second region, and is simultaneously fixed to the first region and the second region.

According to the above-described aspects of the present invention, versatility can be enhanced, and costs can be reduced.

### BRIEF DESCRIPTION OF THE DRAWINGS

FIG. 1 is a top-down view of an electronic apparatus according to an embodiment.

FIG. 2 is a plan view schematically illustrating an internal structure of a chassis.

FIG. 3 is a schematic plan view of a ground pad.

FIG. 4 is a perspective view of a first support.

FIG. 5 is a perspective view of a second support.

FIG. 6A is a schematic plan view of a state in which the first support is fixed to the ground pad.

FIG. 6B is a plan view illustrating a state in which a support member illustrated in FIG. 6A is rotated to a locked position.

FIG. 7A is a schematic plan view of a state in which a stud member of a second support is fixed to the ground pad.

FIG. 7B is a plan view illustrating a state in which a screw is tightened to the stud member illustrated in FIG. 7A.

FIG. 8 is a schematic plan view of a ground pad illustrated in a first modification example.

FIG. 9 is a schematic plan view of a ground pad illustrated in a second modification example.

### DETAILED DESCRIPTION OF THE INVENTION

An electronic apparatus and a circuit board according to the present invention will be described in detail below with embodiments with reference to the accompanying drawings.

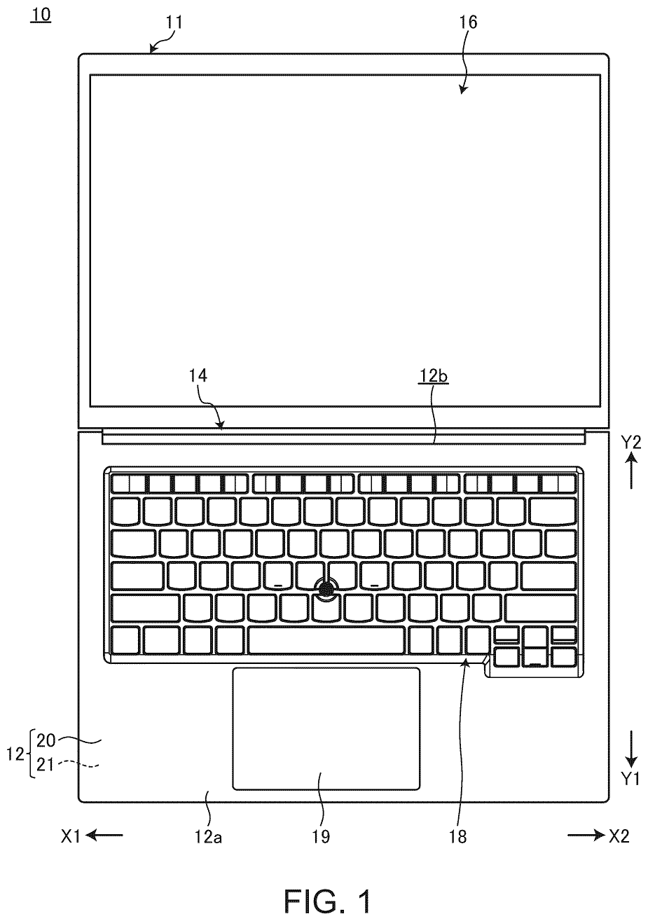

FIG. 1 is a top-down view of an electronic apparatus 10 according to an embodiment. The electronic apparatus 10 of the present embodiment is a clamshell-type laptop PC, as illustrated in FIG. 1. The electronic apparatus 10 has a configuration in which a lid 11 and a chassis 12 are coupled by a hinge 14 to be rotationally movable relative to each other. The electronic apparatus 10 is exemplified as a laptop PC in the present embodiment, but the electronic apparatus may be an apparatus other than the laptop PC, for example, a desktop PC, a tablet PC, a smartphone, a portable game console, or the like.

The lid 11 includes a thin, flat, box-shaped chassis. The lid 11 is equipped with a display 16. The display 16 is, for example, an organic EL display or a liquid crystal display.

The chassis 12 is a thin flat box. A keyboard device 18 and a touchpad 19 face an upper surface (surface 12a) of the chassis 12. The following descriptions of the chassis 12 and each component mounted therein will be made based on an operator's posture when operating the keyboard device 18, and a width direction (left and right) of the chassis 12 will be respectively referred to as X1 and X2 directions, a depth direction (front and rear) of the chassis 12 will be respectively referred to as Y1 and Y2 directions, and a thickness direction (up and down) of the chassis 12 will be respectively referred to as Z1 and Z2 directions. The X1 and X2 directions may be collectively referred to as an X direction, and the Y1 and Y2 directions and the Z1 and Z2 directions may be similarly referred to as a Y direction and a Z direction, respectively. Each of these directions is a direction determined for the convenience of description and may naturally vary depending on the usage state, the installation posture, or the like of the electronic apparatus 10.

The chassis 12 is formed by overlapping and coupling a first cover material 20 and a second cover material 21 in the thickness direction in a mutually detachable manner. The first cover material 20 forms, for example, the upper surface and four peripheral side surfaces of the chassis 12 and has a substantially bathtub shape. The second cover material 21 forms, for example, a lower surface of the chassis 12 and has a substantially flat plate shape. The hinge 14 is installed in a recessed hinge disposition groove 12b formed at a rear edge portion of the chassis 12 and couples the chassis 12 and the lid 11.

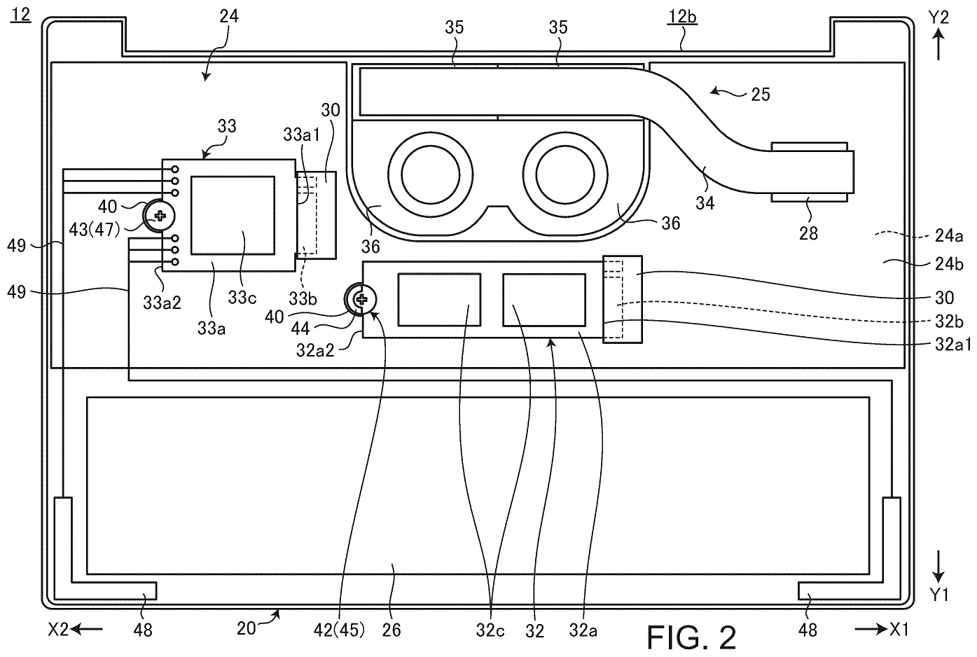

FIG. 2 is a plan view schematically illustrating an internal structure of the chassis 12. FIG. 2 is a view of an interior of the first cover material 20 from a lower surface side, with the second cover material 21 removed.

The interior of the chassis 12 accommodates a circuit board 24, a cooling module 25, and a battery device 26, as illustrated in FIG. 2. The interior of the chassis 12 is further provided with various electronic components, mechanical components, and the like.

The circuit board 24 is a printed circuit board serving as a motherboard of the electronic apparatus 10. The circuit board 24 is disposed closer to a Y2 side of the chassis 12 and extends in the X direction. The circuit board 24 includes a central processing unit (CPU) 28 and a pair of connectors 30 and 30 mounted thereon. The CPU 28 is a processing device that performs primary control and computational operations for the electronic apparatus 10. The connector 30 conforms to a predetermined connection standard, in the present embodiment, the M.2 (m dot two) standard. Electronic modules 32 and 33 are connected to the connectors 30, respectively. Specific configurations of the circuit board 24, the electronic modules 32 and 33, and peripheral parts thereof will be described below. Various electronic components, such as a graphics processing unit (GPU) and a memory, can further be mounted on the circuit board 24. The circuit board 24 includes, for example, a Z1-side surface (first surface 24a) serving as an attachment surface for the first cover material 20 and a Z2-side surface (second surface 24b) serving as a mounting surface for the CPU 28 and the connector 30. It goes without saying that the shape, the disposition, the mounted electronic components, and the like of the circuit board 24 are not limited to the above.

The cooling module 25 can absorb heat generated by the CPU 28 and dissipate the heat to the outside of the chassis 12. The cooling module 25 includes a heat pipe 34, a pair of heat sinks 35 and 35, and a pair of fans 36 and 36. The cooling module 25 can transport the heat from the CPU 28 to each heat sink 35 via the heat pipe 34 and can promote the heat dissipation of each heat sink 35 by using the airflow from each fan 36.

The battery device 26 is a rechargeable battery that serves as a power source for the electronic apparatus 10. The battery device 26 is disposed closer to a Y1 side of the circuit board 24 and extends in the X direction.

Next, specific configuration examples of the circuit board 24 and the electronic modules 32 and 33, and the support structure of the electronic modules 32 and 33 with respect to the circuit board 24 will be described.

First, the circuit board 24 is a printed circuit board in which a predetermined conductive pattern is formed on the second surface 24b of a plate material having insulating properties. The circuit board 24 may have a configuration in which conductive patterns are formed on both surfaces 24a and 24b.

The circuit board 24 includes the connectors 30, a pair of ground pads 40 and 40, and a pair of supports 42 and 43, as illustrated in FIG. 2.

The connector 30 is mounted on the second surface 24b. The mounting type of the connector 30 is not limited, and for example, a plug-in mounting type (Pcie Gen3: PCI Express 3.0), an on-board mounting type (Pcie Gen4: PCI Express 4.0), or the like can be used.

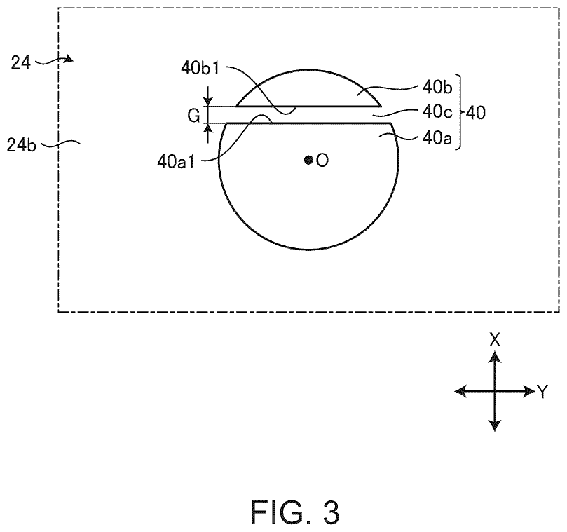

FIG. 3 is a schematic plan view of the ground pad 40.

The ground pads 40 are portions to which the supports 42 and 43 are fixed by soldering (refer to FIG. 2). The ground pad 40 includes a first region 40a, a second region 40b, and a void region 40c, as illustrated in FIG. 3. The first and second regions 40a and 40b are formed of metal patterns. The metal pattern is, for example, a copper foil printed with a silk screen. The void region 40c separates the regions 40a and 40b from each other by being provided with no metal pattern. Therefore, the supports 42 and 43 are not soldered to the void region 40c itself.

The ground pad 40 has, as a whole, a shape of a circle formed by combining the regions 40a to 40c. The circle is not limited to a perfect circle and includes concepts such as a circle slightly distorted from a perfect circle, or an ellipse. The void region 40c is formed in a strip shape passing through a position shifted from a center O of the circle constituting the ground pad 40.

The first region 40a is formed of a metal pattern with a larger area than the second region 40b. The first region 40a has a shape with a part of the circle cut off, for example, a substantially D-shape. That is, the first region 40a has a straight cut line 40al at a boundary with the void region 40c.

The second region 40b is formed of a metal pattern with a smaller area than the first region 40a. The second region 40b is the remaining cut-off end portion of the partially cut circle and has a shape that can be referred to as a dish shape or a crescent shape with one side formed by a straight line. That is, the second region 40b has a straight cut line 40b1 at a boundary with the void region 40c on a side opposite to an arc that forms an outer shape of the entire ground pad 40.

The void region 40c is a straight strip-shaped portion having a predetermined width. The void region 40c is a blank portion that is not soldered when the first support 42 is soldered to the first region 40a and that is for preventing the first support 42 from moving to a second region 40b side. The width of the void region 40c, that is, the width of a gap G between the regions 40a and 40b, may be set to a distance such that the first support 42 cannot move beyond the void region 40c to the second region 40b side during the soldering of the first support 42, which will be described below. For example, the width of the gap G can be set to about 0.5 to 1.0 mm in a case where the diameter of the circle constituting the ground pad 40 is 10 mm.

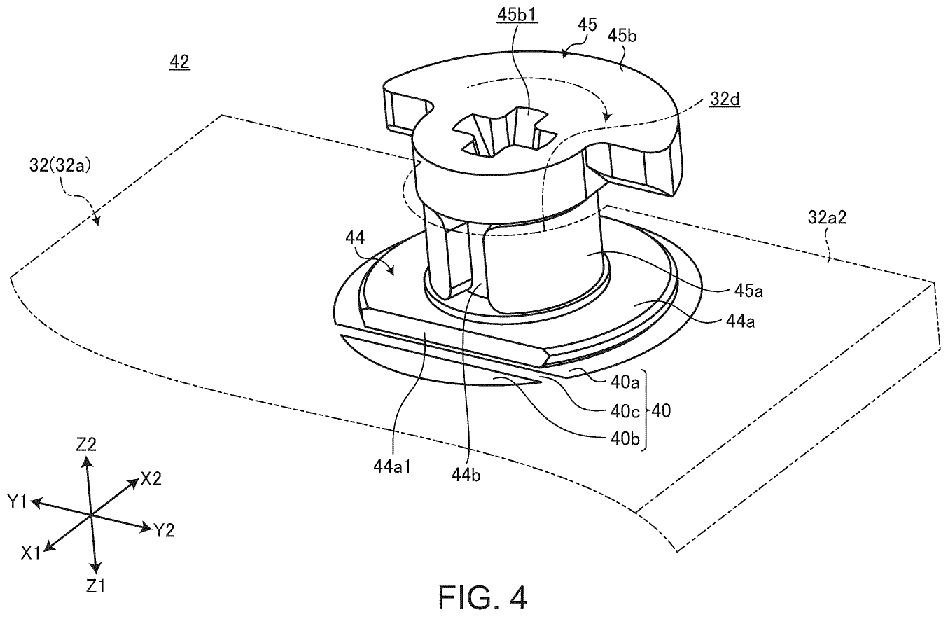

FIG. 4 is a perspective view of the first support 42. The first support 42 includes a stud member 44 and a support member 45, as illustrated in FIGS. 2 and 4. The first support 42 is a locking component that can switch between a locked position (closed position) where the electronic module 32 is supportable, and an unlocked position (open position) by, for example, rotating the cam-shaped support member 45 by 180 degrees.

The stud member 44 is a metal component including a flange 44a and a shaft 44b. The flange 44a is a metal disc shaped by cutting off a part of a circle at a cut surface 44al. The outer shape of the flange 44a is substantially similar to the outer shape of the first region 40a and is the same as or slightly smaller than the outer shape of the first region 40a. That is, the flange 44a is a disc with a substantially D-shape similar to the contour of the first region 40a and has a shape that fits within the first region 40a. The shaft 44b is integrally formed with the flange 44a and is a circular column extending upright in the Z direction from the center of the flange 44a.

The support member (locking member) 45 is a metal component that includes a rotary shaft part 45a and a locking part 45b. The rotary shaft part 45a is a tubular body that is externally fitted onto the shaft 44b to be rotatable relative to the shaft 44b. The locking part 45b is fixed to a Z2-side end surface of the rotary shaft part 45a and is rotatable around an axis of the shaft 44b together with the rotary shaft part 45a. The locking part 45b has, for example, a shape formed by combining two semicircular metal plates, one large and one small. More specifically, the locking part 45b has a substantially cam shape or a substantially mushroom shape in plan view. A small-diameter portion of the locking part 45b is fixed to the shaft 44b, and an operation hole 45b1 is formed at the center thereof. The operation hole 45b1 is, for example, a cross-shaped hole into which a tool such as a Phillips screwdriver is fitted for a rotational operation. A large-diameter portion of the locking part 45b is integrally formed with the small-diameter portion and is pivotable around the axis of the shaft 44b.

The Z-direction height of the shaft 44b, that is, the distance from a Z2-side surface of the flange 44a to a Z1-side surface of the locking part 45b, is greater than the plate thickness of the electronic module 32.

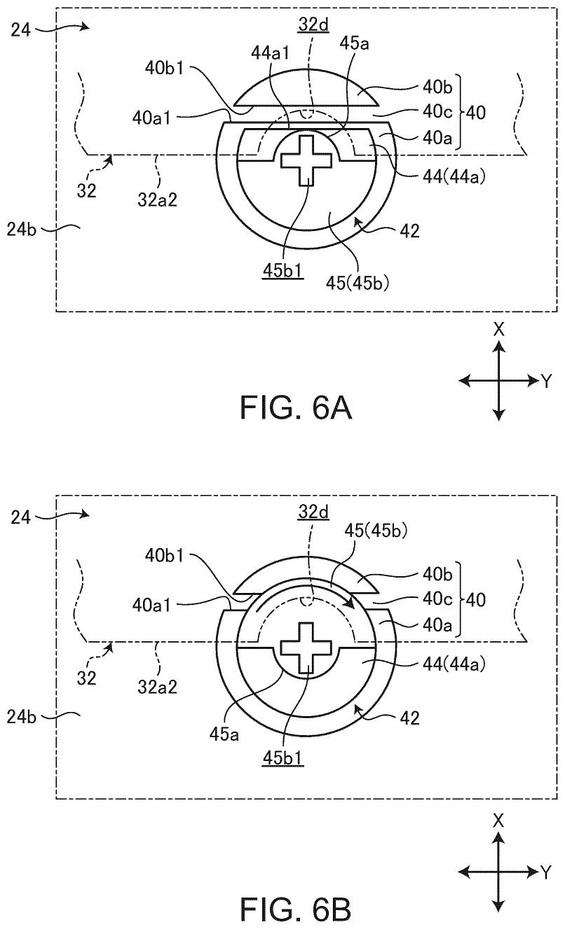

Consequently, the first support 42 can switch between the locked position (refer to FIGS. 2 and 6B) where the other end 32a2 of the electronic module 32, which will be described below, is supported by being pressed from a Z2 side at the large-diameter portion of the locking part 45b, and the unlocked position (refer to FIGS. 4 and 6A) where the other end 32a2 is released without being pressed.

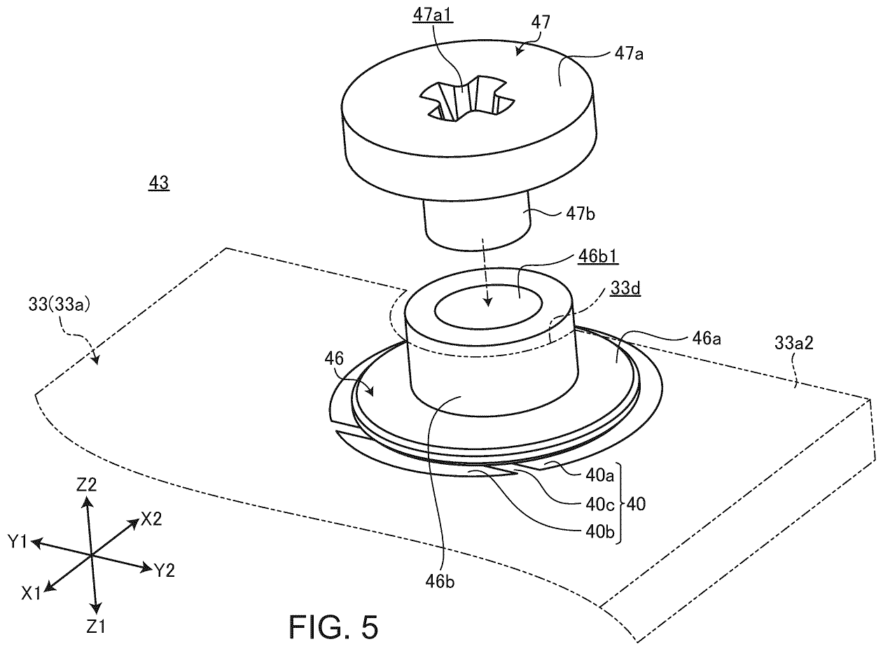

FIG. 5 is a perspective view of the second support 43. The second support 43 includes a stud member 46 and a screw 47, as illustrated in FIGS. 2 and 5. The second support 43 is a component that supports the electronic module 33 by tightening the screw 47 to the stud member 46.

The stud member 46 is a metal component including a flange 46a and a cylinder body 46b. The flange 46a is a metal disc. The outer shape of the flange 46a is a circle that is substantially similar to the overall outer shape formed by combining the regions 40a to 40c of the ground pad 40, and is the same as or slightly smaller than the overall outer shape of the ground pad 40. That is, the flange 46a is a disc with a contour similar to the overall contour of the ground pad 40 and has a shape that fits within the overall contour of the ground pad 40. The cylinder body 46b is integrally formed with the flange 46a and is a cylinder that extends upright in the Z direction from the center of the flange 46a. The cylinder body 46b is provided with a threaded hole 46b1 including a female thread formed on an inner peripheral surface thereof.

The screw 47 is a metal screw including a head part 47a having an outer shape that is substantially the same as the outer shape of the flange 46a, and a threaded part 47b that can be screwed into the threaded hole 46b1. An operation hole 47a1 is formed at the center of the head part 47a. The operation hole 47a1 is, for example, a cross-shaped hole into which a tool such as a Phillips screwdriver is fitted for a rotational operation.

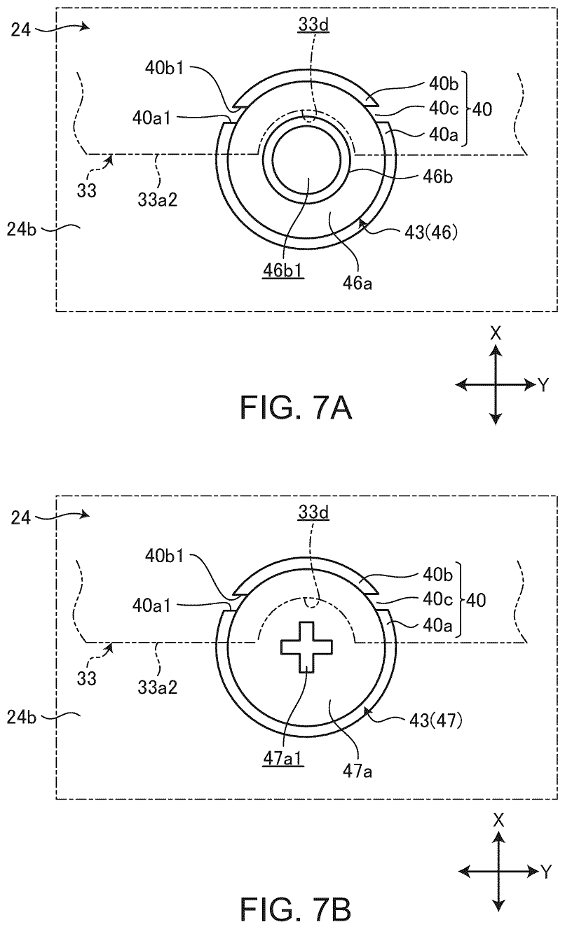

The Z-direction height of the cylinder body 46b, that is, the distance from a Z2-side surface of the flange 46a to a Z1-side surface of the head part 47a of the screw 47 tightened in the threaded hole 46b1, is greater than the plate thickness of the electronic module 33. Consequently, the second support 43 can press and support the other end 33a2 of the electronic module 33, which will be described below, from the Z2 side with the screw 47 (refer to FIGS. 2 and 7B).

Next, the electronic modules 32 and 33 are card-type module components that can be connected to the connectors 30 conforming to the M.2 standard as described above.

The electronic module 32 is, for example, a storage device. The electronic module 32 of the present embodiment is a solid state drive (SSD). The electronic module 32 includes a module substrate 32a, a terminal 32b formed at one end 32a1 of the module substrate 32a, and a semiconductor chip 32c mounted on the module substrate 32a, as illustrated in FIG. 2. In the electronic module 32, the other end 32a2 of the module substrate 32a is pressed in the Z direction by the first support 42 with the terminal 32b connected to the connector 30. Consequently, the electronic module 32 is attached to the circuit board 24. A semicircular notch 32d in which the rotary shaft part 45a of the first support 42 can be disposed is formed at the longitudinal center of the other end 32a2 (refer to FIG. 4).

The electronic module 33 is, for example, a communication module. The electronic module 33 of the present embodiment is compatible with a wireless wide area network (WWAN). The communication standard with which the electronic module 33 is compatible may be, for example, a wireless local area network (WLAN) or the like. The electronic module 33 includes a module substrate 33a, a terminal 33b formed at one end 33a1 of the module substrate 33a, and a semiconductor chip 33c mounted on the module substrate 33a, as illustrated in FIG. 2. In the electronic module 33, the other end 33a2 of the module substrate 33a is pressed in the Z direction by the second support 43 with the terminal 33b connected to the connector 30. Consequently, the electronic module 33 is attached to the circuit board 24. A semicircular notch 33d in which the cylinder body 46b of the second support 43 can be disposed is formed at the longitudinal center of the other end 33a2. A cable 49 from an antenna element 48 installed at each location of the chassis 12 or the lid 11 is appropriately connected to the other end 33a2 of the electronic module 33.

Next, a fixing method of the supports 42 and 43 to the ground pad 40 and a support method of the electronic modules 32 and 33 using the supports 42 and 43 will be described.

FIG. 6A is a schematic plan view of a state in which the first support 42 is fixed to the ground pad 40. FIG. 6B is a plan view illustrating a state in which the support member 45 illustrated in FIG. 6A is rotated to the locked position.

The first support 42 is fixed to the first region 40a of the ground pad 40, as illustrated in FIG. 6A. The first support 42 can be fixed to the first region 40a by reflow soldering a bottom surface (Z1-side surface) of the flange 44a. The fixation of the first support 42 can be simultaneously performed with, for example, a process of mounting the connector 30 or other mounting components on the circuit board 24 by reflow soldering.

The first support 42 may be fixed to the ground pad 40 in a rotational posture (refer to FIG. 6A) where the support member 45 (locking part 45b) is in the unlocked position. The electronic module 32 can be easily attached to the first support 42 fixed to the ground pad 40 when the support member 45 is in the unlocked position. On the other hand, the operator needs to first perform an operation for the unlocked position and attach the electronic module 32 in a case where the support member 45 is in the locked position, which results in decreased work efficiency.

Here, the flange 44a tends to rotate on the first region 40a due to the surface tension of the heated and melted solder when the flange 44a is fixed to the first region 40a by reflow soldering. Therefore, the support member 45 (locking part 45b) may be in the locked position when the solder has solidified, assuming that the first region 40a and the flange 44a are circular.

In this regard, the first region 40a has a substantially D-shape in plan view, that is, a rotationally asymmetric shape, in the ground pad 40 of the present embodiment. The flange 44a has a shape that fits within the first region 40a. The planar shape of the flange 44a is a substantially D-shape corresponding to the first region 40a, that is, a rotationally asymmetric shape. Therefore, the circuit board 24 of the present embodiment allows, when the flange 44a is fixed to the first region 40a by reflow soldering, the flange 44a to be positioned in a fixed rotation direction illustrated in FIG. 6A on the first region 40a due to the surface tension of the heated and melted solder. Specifically, the cut surface 44al is disposed along the cut line 40al. Consequently, the first support 42 can be fixed to the ground pad 40 with the rotation direction controlled such that the locking part 45b is consistently in the unlocked position illustrated in FIG. 6A.

Therefore, the other end 32a2 can be smoothly placed immediately next to the first support 42 in the unlocked position after the terminal 32b is connected to the connector 30, when the electronic module 32 is attached to the circuit board 24 of the present embodiment. Then, the support member 45 is rotated to the locked position (refer to an arrow in FIG. 6B). Consequently, the circuit board 24 can easily support the electronic module 32 by using the first support 42, and high work efficiency can be obtained.

FIG. 7A is a schematic plan view of a state in which the stud member 46 of the second support 43 is fixed to the ground pad 40. FIG. 7B is a plan view illustrating a state in which the screw 47 is tightened to the stud member 46 illustrated in FIG. 7A.

The second support 43 is disposed to span the regions 40a to 40c of the ground pad 40 and is simultaneously fixed to the regions 40a and 40b, as illustrated in FIG. 7A. The second support 43 can be fixed to the regions 40a and 40b by reflow soldering a bottom surface (Z1-side surface) of the flange 46a. The fixation of the second support 43 can be simultaneously performed with, for example, a process of mounting the first support 42, the connector 30, or the like on the circuit board 24 by reflow soldering.

Here, the flange 46a tends to rotate on regions 40a to 40c due to the surface tension of the heated and melted solder even when the flange 46a of the second support 43 is fixed to the ground pad 40 by reflow soldering. However, the second support 43 has a structure that supports the electronic module 33 by using the screw 47. Therefore, the rotational posture of the stud member 46 on the ground pad 40 does not matter, and there is no need to perform control in a fixed direction during fixation.

The ground pad 40 of the present embodiment has an overall outer shape formed by combining the regions 40a to 40c, which is an outer shape that is the same as or slightly larger than the flange 46a, and is circular in plan view. Meanwhile, the flange 46a has a shape that fits within the regions 40a to 40c and is circular in plan view. Therefore, the circuit board 24 of the present embodiment enables reliable fixation to the ground pad 40, even though the flange 46a rotates on the regions 40a to 40c due to the surface tension of the heated and melted solder when the flange 46a is fixed to span the regions 40a to 40c by reflow soldering.

Accordingly, the other end 33a2 can be smoothly placed immediately next to the stud member 46 fixed to the ground pad 40 after the terminal 33b is connected to the connector 30, when the electronic module 33 is attached to the circuit board 24 of the present embodiment. Then, the screw 47 is screwed into the threaded hole 46b1 (refer to FIG. 7B). Consequently, the circuit board 24 can easily support the electronic module 33 by using the second support 43, and high work efficiency can be obtained.

The circuit board 24 of the present embodiment includes the ground pad 40 provided on the surface (second surface 24b) and capable of fixing the support 42 or 43 that supports the other ends 32a2 and 33a2 of the electronic modules 32 and 33, as described above. The ground pad 40 includes the first region 40a formed of a metal pattern, the second region 40b formed of a metal pattern with a smaller area than the first region 40a, and the void region 40c that separates the regions 40a and 40b from each other by being provided with no metal pattern. The ground pad 40 can selectively fix the first support 42 that fits within the first region 40a, and the second support 43 that extends beyond the void region 40c and spans the regions 40a and 40b. The ground pad 40 allows, in a case where the first support 42 is fixed to the first region 40a, the rotation direction of the first support 42 to be positioned in the fixed direction.

Therefore, the circuit board 24 of the present embodiment need only use only the first region 40a when the first support 42, which is a locking component that can switch between supporting and not supporting the electronic module 32 by rotating the support member 45, is fixed to the ground pad 40. This enables the first support 42 to be fixed to the ground pad 40 with the fixed rotation direction consistently controlled. As a result, the efficiency of attaching and detaching the electronic module 32 by using the first support 42 is improved. The circuit board 24 need only simultaneously use the regions 40a and 40b when the second support 43 that supports the electronic module 33 is fixed to the ground pad 40 by using the screw 47. This makes it possible for the circuit board 24 to reliably fix the stud member 46 of the second support 43, which does not require control of the rotation direction, to the ground pad 40. As a result, the circuit board 24 can also support the electronic module 33 by using the second support 43.

The ground pad 40 can selectively fix the supports 42 and 43, which have different support structures for the electronic module, by including regions 40a to 40c in this manner. As a result, since the circuit board 24 is compatible with the use of either one or both of the supports 42 and 43, high versatility can be obtained, and product costs can be reduced. Accordingly, the electronic apparatus 10 including such a circuit board 24 can flexibly select the supports 42 and 43 in accordance with the specifications and applications thereof by mounting the circuit board 24 provided with the same ground pad 40.

The first region 40a may have a rotationally asymmetric shape. Therefore, the flange 44a of the first support 42 is formed in a similar shape, so that it is possible to easily position the rotation direction of the first support 42 in the fixed direction during soldering even with a simple configuration.

A configuration has been illustrated in FIG. 2 in which the electronic module 32, which is a storage device (SSD), is supported by the first support 42 and the electronic module 33, which is a communication module, is supported by the second support 43. However, a configuration can also be employed in which the electronic module 32 is supported by the second support 43 and the electronic module 33 is supported by the first support 42. Only the first support 42 may be fixed to all the ground pads 40, or only the second support 43 may be fixed to all the ground pads 40, in the circuit board 24.

The shape of the ground pad is not limited to the above, and various shapes can be used as long as two or more types of supports can be selectively fixed.

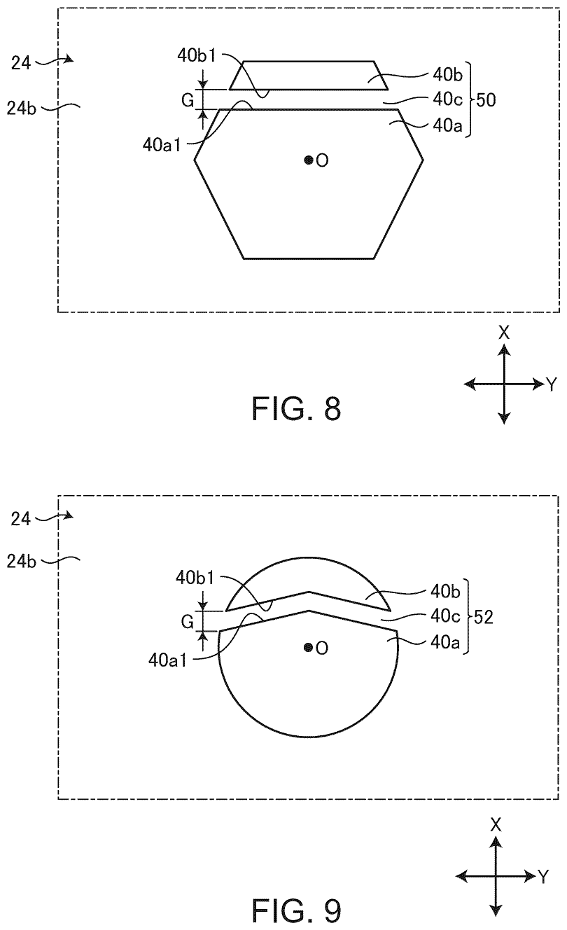

FIG. 8 is a schematic plan view of the ground pad 50 illustrated in a first modification example. Since the same reference numerals as those illustrated in FIGS. 1 to 7B indicate the same or similar configurations in FIG. 8, detailed descriptions are omitted as the same or similar functions and effects are provided, and the same applies to FIG. 9.

A ground pad 50 illustrated in FIG. 8 has, as a whole, a shape of a polygon (a hexagon in FIG. 8) formed by combining the regions 40a to 40c. The ground pad 50 also includes the void region 40c formed in a strip shape passing through a position shifted from the center O of the polygon constituting the ground pad 50. Therefore, the ground pad 50 can also selectively fix the first support 42 including the flange 44a that has a shape corresponding to the first region 40a, and the second support 43 including the flange 46a that extends beyond the void region 40c and spans the regions 40a and 40b.

FIG. 9 is a schematic plan view of a ground pad 52 illustrated in a second modification example. The ground pad 52 illustrated in FIG. 9 is the same as the ground pad 40 illustrated in FIG. 3 in that the shape formed by combining the regions 40a to 40c is a circle as a whole. The ground pad 52 differs from the ground pad 40 in that the void region 40c has a bent strip shape instead of a straight line shape. The void region 40c is not limited to the straight line shape and may be bent or curved as long as the void region 40c separates the regions 40a and 40b from each other, as illustrated in FIG. 9.

It should be noted that the present invention is not limited to the embodiments described above and can, obviously, be freely modified within the scope that does not deviate from the gist of the present invention.

### DESCRIPTION OF SYMBOLS

10 electronic apparatus
12 chassis
24 circuit board
30 connector
32, 33 electronic module
40, 50, 52 ground pad
40a first region
40b second region
40c void region
42 first support
43 second support
44, 46 stud member
45 support member
47 screw

What is claimed is:

1. A circuit board on which a connector for connecting one end of an electronic module is mounted, comprising:
a ground pad provided on a surface and configured to fix a first or second support configured to support the other end of the electronic module,
wherein the ground pad includes
a first region formed of a metal pattern,
a second region formed of a metal pattern with a smaller area than the first region, and
a void region configured to separate the first region and the second region from each other by being provided with no metal pattern, and
the ground pad is configured to selectively fix the first support that fits within the first region, and the second support that extends beyond the void region and spans the first region and the second region, and allows, in a case where the first support is fixed to the first region, a rotation direction of the first support to be positioned in a fixed direction.

2. The circuit board according to claim 1,
wherein the first region has a rotationally asymmetric shape.

3. The circuit board according to claim 1,
wherein the ground pad has, as a whole, a shape of a circle or a polygon formed by combining the first region, the void region, and the second region, and
the void region is formed in a strip shape passing through a position shifted from a center of the circle or the polygon.

4. An electronic apparatus, comprising:
a circuit board to which an electronic module is connected,
wherein the circuit board includes
a connector mounted on a surface and to which one end of the electronic module is connected,
a ground pad provided on the surface, and
a support fixed to the ground pad and configured to support the other end of the electronic module,
the ground pad includes
a first region formed of a metal pattern,
a second region formed of a metal pattern with a smaller area than the first region, and
a void region configured to separate the first region and the second region from each other by being provided with no metal pattern, and
the support has a shape that fits within the first region, and is fixed to the first region with a rotation direction of the support positioned in a fixed direction.

5. The electronic apparatus according to claim 4,
wherein the support includes
a stud member including a flange fixed to the ground pad and a shaft extending upright from a surface of the flange, and
a support member supported to be rotatable relative to the shaft and configured to support the other end of the electronic module, and
the support member is configured to switch between a locked position, where the other end is supported, and an unlocked position, where the other end is not supported, by rotating with respect to the shaft.

6. An electronic apparatus, comprising:
a circuit board to which an electronic module is connected,
wherein the circuit board includes
a connector mounted on a surface and to which one end of the electronic module is connected,
a ground pad provided on the surface, and
a support fixed to the ground pad and configured to support the other end of the electronic module,
the ground pad includes
a first region formed of a metal pattern,
a second region formed of a metal pattern with a smaller area than the first region, and
a void region configured to separate the first region and the second region from each other by being provided with no metal pattern, and
the support has a shape that extends beyond the void region and spans the first region and the second region, and is simultaneously fixed to the first region and the second region.

7. The electronic apparatus according to claim 6,
wherein the support includes
a stud member including a flange fixed to the ground pad, and a cylinder body formed with a threaded hole and extending upright from the flange, and
a screw configured to support the other end of the electronic module by being screwed into the threaded hole.

8. The electronic apparatus according to claim 4,
wherein the first region has a rotationally asymmetric shape.
